(19) United States
(12) Patent Application Publication
(10) Pub. No.: US 2006/0030156 A1
(43) Pub. Date: Feb. 9, 2006

(54) Abrasive conductive polishing article for electrochemical mechanical polishing

(75) Inventors: Paul D. Butterfield, San Jose, CA (US); Ralph M. Wadensweiler, Sunnyvale, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/194,432

(22) Filed: Aug. 1, 2005

Related U.S. Application Data
(60) Provisional application No. 60/599,001, filed on Aug. 5, 2004.

(51) Int. Cl. H01L 21/302; B24B 29/00

(52) U.S. Cl. 438/691; 438/689; 451/285

(57) ABSTRACT

Articles of manufacture and processes for planarizing a layer on a substrate are provided. In one aspect, a process is provided for manufacturing a polishing article comprising combining a conductive material component and components of a binder material to form a composite material, at least partially curing the composite material, and introducing abrasive particles of about 0.01 inches or greater in diameter to form an abrasive-containing composite material.

### CROSS-REFERENCE TO RELATED APPLICATIONS

This application claims benefit of U.S. Provisional Patent Application Ser. No. 60/599,001, filed Aug. 5, 2004, which is hereby incorporated by reference.

### BACKGROUND OF THE INVENTION

1. Field of the Invention

The present invention relates to an article of manufacture, an apparatus, and a process for planarizing a substrate surface.

2. Background of the Related Art

Electrochemical Mechanical Processing (ECMP) is a technique used to remove conductive materials from a substrate surface by electrochemical dissolution while concurrently polishing the substrate with reduced mechanical abrasion as compared to conventional Chemical Mechanical Polishing (CMP) processes. ECMP systems may generally be adapted for deposition of conductive material on the substrate by reversing the polarity of the bias. Electrochemical dissolution is performed by applying a bias between a cathode and a substrate surface to remove conductive materials from the substrate surface into a surrounding electrolyte. A mechanical component of the polishing process is performed by providing relative motion between the substrate and the polishing material that enhances the removal of the conductive material from the substrate.

A conductive layer previously deposited on a substrate is one material that may be polished using electrochemical mechanical polishing. During electrochemical processing, a substrate having a conductive layer thereon is urged against a polishing surface and the conductive layer disposed on the substrate is electrically biased through the polishing surface relative to an electrode typically below the polishing surface. An electrolyte fluid is disposed between the conductive layer and the electrode. The electrolyte completes an electrical circuit between the substrate and the electrode, which assists in the removal of a portion of the conductive material and other materials from the surface of the substrate.

The electrical bias may be applied to the substrate surface by a polishing pad having a conductive upper surface. Polishing pads having a conductive upper surface have been developed and abrasive particles have been added to the upper surface to effect planarization by combining physical abrasion and electrochemical activity. However, the size and the distribution of the abrasive particles may inhibit conduction and the pad may exhibit non-uniform distribution of electrical current over the substrate surface. This non-uniform electrical distribution may result in non-uniform or variable dissolution, and hence, diminished removal of material from the substrate surface.

As a result, there is a need for an improved polishing article for the removal of material on a substrate surface.

### SUMMARY OF THE INVENTION

Aspects of the invention generally provide an article of manufacture and an apparatus for planarizing a layer on a substrate using electrochemical deposition techniques, electrochemical dissolution techniques, polishing techniques, and/or combinations thereof.

In one aspect, a process is provided for manufacturing a polishing article comprising combining a conductive material component and components of a binder material component to form a composite material, at least partially curing the composite material, and introducing abrasive particles of about 0.01 inches or greater in diameter to form an abrasive-containing composite material.

In another aspect, a polishing article is provided for processing a substrate surface, such as a conductive layer deposited on the substrate surface. The polishing article includes a conductive polishing layer comprising a soft conductive material, a binder material, and abrasive particles of about 0.01 inches or greater in diameter and an article support layer coupled to and disposed below the conductive polishing layer.

### BRIEF DESCRIPTION OF THE DRAWINGS

So that the manner in which the above recited aspects of the invention are attained and can be understood in detail, a more particular description of the invention, briefly summarized above, may be had by reference to embodiments thereof which are illustrated in the appended drawings.

It is to be noted, however, that the appended drawings illustrate only typical embodiments of this invention and, therefore, are not to be considered limiting of its scope, for the invention may admit to other equally effective embodiments.

FIG. 1 is a plan view of one embodiment of a processing system.

FIG. 2 is a sectional view of one embodiment of a first electrochemical mechanical planarizing (ECMP) station of the system of FIG. 1.

FIG. 3 is a partial cross-sectional view of one embodiment of a polishing article.

FIG. 4 is another embodiment of a polishing article having a window formed therein.

FIGS. 5-7 are sectional views of alternate embodiments of a polishing article.

To facilitate understanding, identical reference numerals have been used, wherever possible, to designate identical elements that are common to the figures.

### DETAILED DESCRIPTION

The words and phrases used herein should be given their ordinary and customary meaning in the art by one skilled in the art unless otherwise further defined.

Polishing Apparatus

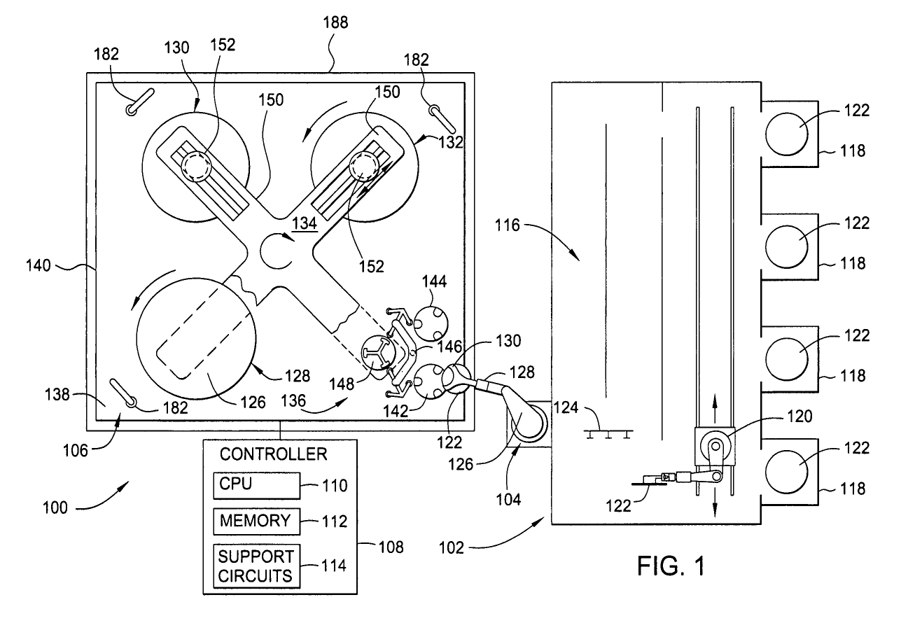

FIG. 1 is a plan view of one embodiment of a processing system 100 having an apparatus for electrochemically processing a substrate. The exemplary system 100 generally comprises a factory interface 102, a loading robot 104, and a planarizing module 106. The loading robot 104 is disposed proximate the factory interface 102 and the planarizing module 106 to facilitate the transfer of substrates 122 therebetween.

A controller 108 is provided to facilitate control and integration of the modules of the system 100. The controller 108 comprises a central processing unit (CPU) 110, a memory 112, and support circuits 114. The controller 108 is coupled to the various components of the system 100 to facilitate control of, for example, the planarizing, cleaning, and transfer processes.

The factory interface 102 generally includes a cleaning module 116 and one or more wafer cassettes 118. An interface robot 120 is employed to transfer substrates 122 between the wafer cassettes 118, the cleaning module 116 and an input module 124. The input module 124 is positioned to facilitate transfer of substrates 122 between the planarizing module 106 and the factory interface 102 by grippers, for example vacuum grippers or mechanical clamps.

The planarizing module 106 includes at least one polishing station 130 that is adapted to perform an electrochemical mechanical planarization (ECMP) process on a substrate 122. The at least one polishing station 130 is disposed in an environmentally controlled enclosure 188. Examples of planarizing modules 106 that can be adapted to benefit from the invention include MIRRA®, MIRRA MESA®, REFLEXION®, REFLEXION® LK, and REFLEXION LK Ecmp™ Chemical Mechanical Planarizing Systems, all available from Applied Materials, Inc. of Santa Clara, Calif. Other planarizing modules, including those that use processing pads, planarizing webs, or a combination thereof, and those that move a substrate relative to a planarizing surface in a rotational, linear or other planar motion may also be adapted to benefit from the invention.

In the embodiment depicted in FIG. 1, the planarizing module 106 includes a first polishing station 128, a second polishing station 130 and a third polishing station 132. In one embodiment, all of the polishing stations 128, 130, 132 may be adapted to perform an ECMP process. Alternatively, the first and second polishing stations 128, 130 may be adapted to perform an ECMP process on a substrate while the third polishing station 132 may be adapted to perform a conventional chemical mechanical polishing process on a substrate. In one example of a multi-step ECMP process, removal of material disposed on the substrate 122 may be performed through an electrochemical dissolution process at the first polishing station 128 and any remaining material is removed from the substrate at the second polishing station 130 through a multi-step electrochemical mechanical process, wherein part of the multi-step process is configured to remove residual material. The substrate may be further processed at the third polishing station 132 to remove any excess residual material. It is contemplated that more than one ECMP station may be utilized to perform the multi-step removal process after the bulk of the conductive material is removed at a different station. Alternatively, each of the first and second polishing stations 128, 130 may be utilized to perform bulk material removal on a single station. It is also contemplated that all polishing stations 128, 130, and 132 may be configured to process the conductive layer and residual removal on a single station.

The exemplary planarizing module 106 also includes a transfer station 136 and a carousel 134 that are disposed on an upper or first side 138 of a machine base 140. In one embodiment, the transfer station 136 includes an input buffer station 142, an output buffer station 144, a transfer robot 146, and a load cup assembly 148. The input buffer station 142 receives substrates from the factory interface 102 by means of the loading robot 104. The loading robot 104 is also utilized to return polished substrates from the output buffer station 144 to the factory interface 102. The transfer robot 146 is utilized to move substrates between the buffer stations 142, 144 and the load cup assembly 148.

In one embodiment, the transfer robot 146 includes two gripper assemblies, each having pneumatic gripper fingers that hold the substrate by the substrate's edge. The transfer robot 146 may simultaneously transfer a substrate to be processed from the input buffer station 142 to the load cup assembly 148 while transferring a processed substrate from the load cup assembly 148 to the output buffer station 144. An example of a transfer station that may be used to advantage is described in U.S. Pat. No. 6,156,124, issued Dec. 5, 2000, entitled “Wafer Transfer Station for a Chemical Mechanical Polisher,” which is herein incorporated by reference in its entirety to the extent it is not inconsistent with this disclosure.

The carousel 134 is centrally disposed on the base 140. The carousel 134 typically includes a plurality of arms 150, each supporting a carrier head assembly 152. Two of the arms 150 depicted in FIG. 1 are shown in phantom such that the transfer station 136 and a planarizing surface 126 of the polishing station 130 may be seen. The carousel 134 is indexable such that the carrier head assemblies 152 may be moved between the polishing stations 128, 130, 132 and the transfer station 136. One carousel that may be utilized to advantage is described in U.S. Pat. No. 5,804,507, issued Sep. 8, 1998, entitled “Radially Oscillating Carousel Processing System for Chemical Mechanical Polishing,” which is hereby incorporated by reference in its entirety to the extent it is consistent with this disclosure.

A conditioning device 182 is disposed on the base 140 adjacent each of the polishing stations 128, 130, and 132. The conditioning device 182 periodically conditions the planarizing material disposed in the stations 128, 130, 132 to maintain uniform planarizing results.

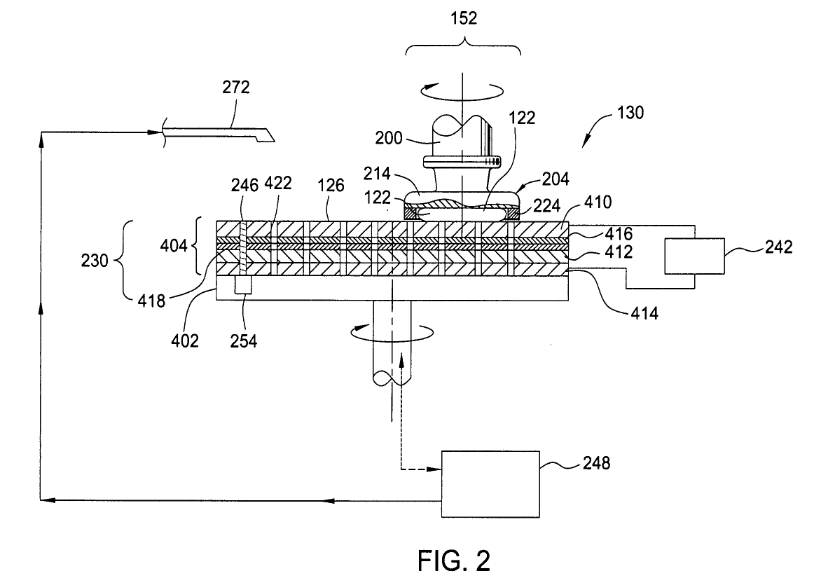

FIG. 2 depicts a sectional view of one of the carrier head assemblies 152 positioned over one embodiment of the polishing station 130. The first and third polishing stations 128, 132 may be similarly configured. The carrier head assembly 152 generally comprises a drive system 200 coupled to a carrier head 204, which generally provides at least rotational motion to the carrier head 204. The carrier head 204 additionally may be actuated toward the polishing station such that the substrate 122 retained in the carrier head 204 may be disposed against the planarizing surface 126 of the polishing station 130 during processing. The drive system 200 is coupled to the controller 108 that provides a signal to the drive system 200 for controlling the rotational speed and direction of the carrier head 204.

In one embodiment, the carrier head may be a TITAN HEAD™ or TITAN PROFILER™ wafer carrier manufactured by Applied Materials, Inc. Generally, the carrier head 204 comprises a housing 214 and retaining ring 224 that defines a center recess in which the substrate 122 is retained. The retaining ring 224 circumscribes the substrate 122 disposed within the carrier head 204 to prevent the substrate from slipping out from under the carrier head 204 while processing. The retaining ring 224 can be made of plastic materials such as PPS, PEEK, and the like, or conductive materials such as stainless steel, Cu, Au, Pd, and the like, or some combination thereof. It is further contemplated that a conductive retaining ring 224 may be electrically biased to control the electric field during ECMP. Conductive or biased retaining rings tend to slow the polishing rate proximate the edge of the substrate. It is contemplated that other carrier heads may be utilized.

The polishing station 130 generally includes a platen assembly 230 that is rotationally disposed on the base 402. An area of the base 402 provides a conduit for the electrical, mechanical, pneumatic, control signals and connections communicating with the platen assembly 230. The platen assembly 230 is typically coupled to a motor (not shown) that provides the rotational motion to the platen assembly 230. The motor is coupled to the controller 108 that provides a signal for controlling for the rotational speed and direction of the platen assembly 230.

A processing pad assembly 404 is disposed on the base 402 to form the platen assembly 230. The processing pad assembly 404 may be retained to the base 402 by magnetic attraction, vacuum, clamps, adhesives and the like.

The platen assembly 230 may be adapted to deliver electrolyte 248 through the processing pad assembly 404, or the platen assembly 230 may have a fluid delivery arm 272 disposed adjacent thereto configured to supply electrolyte to a planarizing surface of the processing pad assembly 404. The platen assembly 402 includes at least one of a meter or sensor 254 to facilitate endpoint detection.

In one embodiment, the processing pad assembly 404 includes a support layer 412, which may also be referred to as a sub-pad or interposed pad, sandwiched between a conductive pad 410 and an electrode 414. The conductive pad 410 is substantially conductive across its top processing surface and is generally made from a conductive material or a conductive composite where, the conductive elements are dispersed integrally with or comprise the material comprising the planarizing surface, such as a polymer matrix having conductive particles dispersed therein.

The conductive pad 410, the interposed pad 412, and the electrode 414 may be fabricated into a single, replaceable assembly. The processing pad assembly 404 is generally permeable or perforated to allow electrolyte to pass between the electrode 414 and top surface 126 of the conductive pad 410. The processing pad assembly 404 may be perforated by apertures 422 to allow electrolyte to flow therethrough from an electrolyte source 248, and into contact with the substrate 122 during processing. It is contemplated that different electrolyte compositions may be provided during different stages of processing.

In one embodiment, the conductive pad 410 is comprised of a conductive material and abrasive material disposed in a polymer matrix, for example, tin particles and cured polyurethane particles disposed in a polymer matrix.

An optional conductive foil 416 may additionally be disposed between the conductive pad 410 and the subpad 412. The foil 416 is coupled to a power source 242 and provides uniform distribution of voltage applied by the source 242 across the conductive pad 410. In embodiments not including the conductive foil 416, the conductive pad 410 may be coupled directly, for example, via a terminal integral to the pad 610, to the power source 242. Additionally, the pad assembly 404 may include an interposed pad 418, which, along with the foil 416, provides mechanical strength to the overlying conductive pad 410. Examples of suitable pad assemblies are described in U.S. patent Publication No. 2004/0023610, filed on Jun. 6, 2003; U.S. Ser. No. 2004/0020789, filed on Jun. 6, 2003; U.S. Ser. No. 2004/0134792, filed on Jun. 26, 2003; and U.S. Ser. No. 2004/0082289, filed on Aug. 15, 2003, all publications entitled “Conductive Polishing Article for Electrochemical Mechanical Polishing,” and all of which are incorporated by reference herein to the extent the publications are not inconsistent with the disclosure and claimed aspects herein.

The electrode 414 is typically comprised of a conductive material, such as stainless steel, copper, aluminum, gold, silver and tungsten, among others. The electrode 414 may be solid, impermeable to electrolyte, permeable to electrolyte or perforated. The electrode 414 is also coupled to the power source 242 so that an electrical potential may be established between the substrate 122 and electrode 414.

A meter (not shown) may be provided to detect a metric indicative of the electrochemical process. The meter may be coupled or positioned between the power source 242 and the electrode 414. The meter may also be integral to the power source 242. In one embodiment, the meter is configured to provide the controller 108 with a metric indicative of processing, such as charge, current and/or voltage. This metric may be utilized by the controller 108 to adjust the processing parameters in-situ or to facilitate endpoint or other process stage detection.

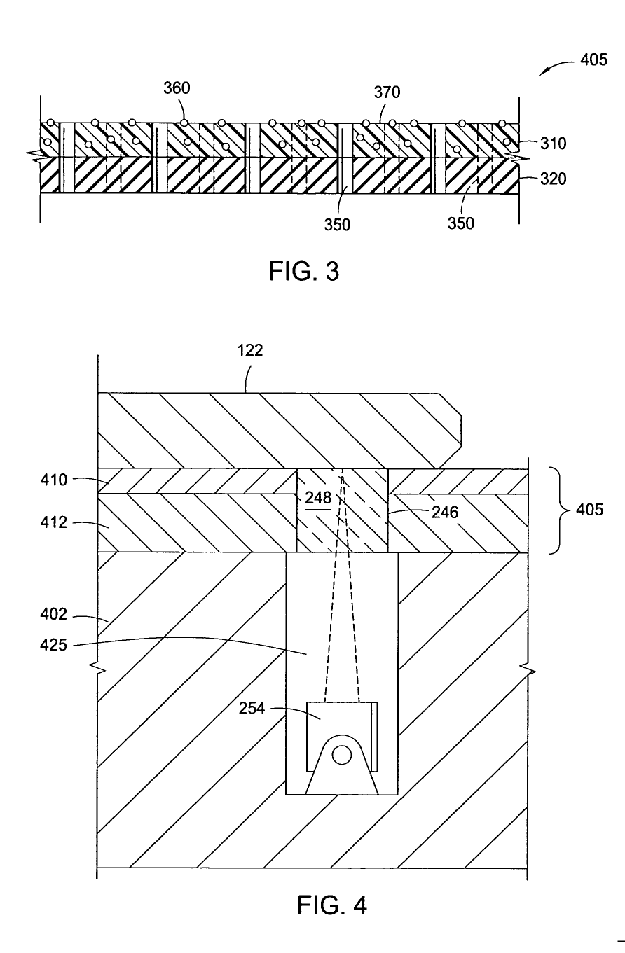

Referring to FIG. 4, a window 246 may be provided through the pad assembly 404. The window 246 may extend through the support layer 412, the conductive surface portion 410, (370 and 310 respectively in FIG. 3) or both. While not shown, the abrasive particles as described herein may be disposed in the conductive surface portion 410 as described for layer 310 in FIG. 3. Further, while not shown, the support layer 412 and the conductive surface portion 410 may be perforated and grooved.

A fluid barrier 248 may be disposed in the window 246 to provide a continual process surface and to prevent polishing compositions and other processing fluids from contacting the sensor 254, for example, disposed in a recess 425 formed in the platen 402. The fluid barrier 248 is generally selected to be transmissive to the signals passing therethrough. The fluid barrier 248 may be a separate element, such as a block of polyurethane disposed within the window 246, or one or more of the layers comprising the polishing assembly 404, for example, a sheet of mylar underlying the conductive surface portion 410 or the article support, or sub-pad, portion 412.

The window 246 allows a sensor 254, positioned below the pad assembly 405, to sense a metric indicative of polishing performance. For example, the sensor 254 may be an eddy current sensor or an interferometer, among other sensors. The metric, provided by the sensor 254 to the controller 108, provides information that may be utilized for processing profile adjustment in-situ, endpoint detection or detection of another point in the electrochemical process. In one embodiment, the sensor 254 is an interferometer capable of generating a collimated light beam which, during processing, is directed at and impinges on a side of the substrate 122 that is being polished. The interference between reflected signals is indicative of the thickness of the conductive layer of material being processed. One sensor that may be utilized to advantage is described in U.S. Pat. No. 5,893,796, issued Apr. 13, 1999, entitled “Forming a Transparent Window in a Polishing Pad for a Chemical Mechanical Polishing Apparatus,”, which is hereby incorporated by reference in its entirety to the extent it is not inconsistent with this disclosure.

The polishing composition for the process is provided from an electrolyte source container, such as source 248 in FIG. 2. Electrolyte solutions may include commercially available electrolytes. For example, in removal of copper containing material, the electrolyte may include sulfuric acid based electrolytes or phosphoric acid based electrolytes, such as potassium phosphate (K₃PO₄), or combinations thereof. The electrolyte may also contain derivatives of sulfuric acid based electrolytes, such as copper sulfate, and derivatives of phosphoric acid based electrolytes, such as copper phosphate. Electrolytes having perchloric acid-acetic acid solutions and derivatives thereof may also be used.

Additionally, the invention contemplates using electrolyte compositions conventionally used in electroplating or electropolishing processes, including conventionally used electroplating or electropolishing additives, such as brighteners among others. One source for electrolyte solutions used for electrochemical processes such as copper plating, copper anodic dissolution, or combinations thereof is Shipley Leonel, a division of Rohm and Haas, headquartered in Philadelphia, Pa., under the tradename Ultrafill 2000. Examples of suitable electrolyte compositions are described in U.S. Pat. No. 6,811,680, entitled “Planarization of Substrates Using Electrochemical Mechanical Polishing,” which issued Nov. 2, 2004; U.S. patent Publication No. 2003/0178320, filed on Feb. 26, 2003; U.S. patent Publication No. 2003/0234184, filed on Jun. 26, 2003, both publications entitled “Method and Composition for Polishing a Substrate;” and U.S. patent Publication No. 2004/0248412, filed on May 14, 2004, entitled “Method and Composition for Fine Copper Slurry for Low Dishing in ECMP,” all of the aforementioned patent and publications are incorporated by reference in their entirety to the extent the patent and publications are not inconsistent with the disclosure and claimed aspects herein.

Electrolyte solutions are provided to the electrochemical cell to provide a dynamic flow rate on the substrate surface or between the substrate surface and an electrode at a flow rate up to about 20 gallons per minute (GPM) for a 300 mm substrate, such as between about 0.5 GPM and about 20 GPM, for example, at about 2 GPM. It is believed that such flow rates of electrolyte are sufficient to evacuate polishing material and chemical by-products from the substrate surface and allow refreshing of electrolyte material for improved polishing rates.

When using mechanical abrasion in the polishing process, the substrate 112 and polishing assembly 404 are rotated relative to one another to remove material from the substrate surface. Mechanical abrasion may be provided by physical contact with both conductive polishing materials and conventional polishing materials as described herein. The substrate 112 and the polishing assembly 404 are respectively rotated at about 5 rpms or greater for a 300 mm substrate, such as between about 10 rpms and about 50 rpms.

In one embodiment, a high rotational speed polishing process may be used. The high rotational speed process includes rotating the polishing article 405 at a platen speed of about 150 rpm or greater, such as between about 150 rpm and about 750 rpm; and the substrate 112 may be rotated at a rotational speed between about 150 rpm and about 500 rpm, such as between about 300 rpm and about 500 rpm. Further description of a high rotational speed polishing process that may be used with the polishing articles, processes, and apparatus described herein is disclosed in U.S. Pat. No. 6,821,881, issued Nov. 23, 2004, and entitled, “Method And Apparatus For Chemical Mechanical Polishing Of Semiconductor Substrates.” Other motion, including orbital motion or a sweeping motion across the substrate surface, may also be performed during the process.

When contacting the substrate surface, a pressure of about 6 psi or less, such as less than about 2 psi is applied between the polishing assembly 404 and the substrate surface. If a substrate containing low dielectric constant material is being polished, a pressure between of less than about 2 psi, such as about 0.5 psi or less is used to urge the substrate 112 against the polishing assembly 404 during polishing of the substrate. In one aspect, a pressure between about 0.1 psi and about 0.2 psi may be used in polishing substrates with conductive polishing articles as described herein.

In anodic dissolution, a potential difference or bias is applied between the electrode 414, performing as a cathode, and the polishing surface 310 (See, FIG. 3) of the polishing assembly 404, performing as the anode. The substrate in contact with the polishing article is polarized via the conductive polishing surface 310 at the same time the bias is applied to the conductive article support member. The application of the bias allows removal of conductive material, such as copper-containing materials, formed on a substrate surface. Establishing the bias may include the application of a voltage of about 15 volts or less to the substrate surface. A voltage between about 0.1 volts and about 10 volts may be used to dissolve copper-containing material from the substrate surface and into the electrolyte. The bias may also produce a current density between about 0.1 milliamps/cm² and about 50 milliamps/cm², or between about 0.1 amps to about 20 amps for a 200 mm substrate.

The signal provided by the power supply 242 to establish the potential difference and perform the anodic dissolution process may be varied depending upon the requirements for removing material from the substrate surface. For example, a time varying anodic signal may be provided. The signal may also be applied by electrical pulse modulation techniques. The electrical pulse modification technique comprises applying a constant current density or voltage over the substrate for a first time period, then applying a constant reverse voltage or stopping applying a voltage over the substrate for a second time period, and repeating the first and second steps. For example, the electrical pulse modification technique may use a varying potential from between about −0.1 volts and about −15 volts to between about 0.1 volts and about 15 volts.

With the correct perforation pattern and density on the polishing media, it is believed that biasing the substrate from the polishing assembly 404 provides uniform dissolution of conductive materials, such as metals, into the electrolyte from the substrate surface as compared to the higher edge removal rate and lower center removal rate from conventional edge contact-pins bias.

Conductive material, such as copper containing material can be removed from at least a portion of the substrate surface at a rate of about 15,000 Å/min or less, such as between about 100 Å/min and about 15,000 Å/min. In one embodiment of the invention where the copper material to be removed is about 12,000 Å thick, the voltage may be applied to the conductive polishing article 405 to provide a removal rate between about 100 Å/min and about 8,000 Å/min.

Following the electropolishing process, the substrate may be further polished or buffed to remove barrier layer materials, remove surface defects from dielectric materials, or improve planarity of the polishing process using the conductive polishing article. An example of a suitable buffing process and composition is disclosed in co-pending U.S. Pat. No. 6,858,540, filed on Aug. 8, 2002, and incorporated herein by reference in its entirety to the extent it is not inconsistent with this disclosure.

Polishing Article Materials

The polishing articles described herein may be formed with a fixed abrasive conductive polishing layer comprising a conductive material disposed in a binder having abrasive material included therein. The conductive material may comprise a soft conductive material such as gold, tin, palladium, palladium-tin alloys, platinum, lead, and combinations thereof. Metal alloys and ceramic composites softer than the material to be polished from the substrate surface, such as softer than copper for polishing copper, may also be used.

The binder material typically comprises a conventional polishing material. In particular, the binder material comprises a dielectric polymeric material. Examples of dielectric polymeric polishing materials include polyurethane and polyurethane mixed with fillers, polycarbonate, polyphenylene sulfide (PPS), polytetrafluoroethylene polymers, polystyrene, ethylene-propylene-diene-methylene (EPDM), or combinations thereof, and other polishing materials used in polishing substrate surfaces, of which polyurethane is preferred. The invention contemplates that any conventional polishing material may be used as a binder material (also known as a matrix) with the conductive material described herein.

Suitable abrasive materials include abrasive particles of ceramic, inorganic, or polymer materials. Examples of inorganic or ceramic particles include alumina, ceria, diamond, silica, titania, zirconia, germania, boron nitride, boron carbide, silicon carbide, and combinations thereof, of which silica and ceria are preferred.

The polymer particles may be closed cell or open cell to tailor the wear rate of the polishing portion. Polymeric particles used in forming the polishing pad are generally non-reactive, such as cured polymeric particles, with the components used to form the binder materials. Cured polyurethane particles may be used with a pad having a polyurethane binder. Polymeric abrasive particles can be added to the components of the binder material prior to curing the binder material to form the polishing article. Cured polymeric particles resist reaction with the binder material during curing and retain the abrasive properties. Examples of polymeric abrasive particles include polyurethane, polymethylmethacrylate, polymethyl acrylate, polystyrene, polymethacrylonitrile, and combinations thereof.

The abrasive particles used in the present polishing article are larger than conventionally used abrasive particles having diameters larger than about 200 microns. Preferred abrasive have diameters of about 0.001 inches or greater, such as about 0.01 inches in diameter. The amount of abrasive particles to be added to the composition may vary, and it is desirous to have sufficient abrasive material to provide an abrasive surface area percentage of the polishing surface of between about 1% and about 50%.

The conductive materials may be used to form conductive polishing materials or articles having bulk or surface resistivity of about 50 Ω-cm or less, such as a resistivity of about 3 Ω-cm or less. In one aspect of the polishing article, the polishing article or polishing surface of the polishing article has a resistivity of about 1 Ω-cm or less. An example of a polishing article surface having the desired resistivity is a polishing article of tin and cured polyurethane abrasives in a polyurethane binder.

The conductive polishing articles formed herein generally have mechanical properties that do not degrade under sustained electric fields and are resistant to degradation in acidic or basic electrolytes. The conductive material and any binder material used are combined to have equivalent mechanical properties, if applicable, of conventional polishing materials used in a conventional polishing article. For example, the conductive polishing material, either alone or in combination with a binder material, has a hardness of about 100 or less on the Shore D Hardness scale for polymeric materials as described by the American Society for Testing and Materials (ASTM), headquartered in Philadelphia, Pa. In one aspect, the conductive material has a hardness of about 80 or less on the Shore D Hardness scale for polymeric materials. The conductive polishing portion 310 generally includes a surface roughness of about 500 microns or less. The properties of the polishing pad are generally designed to reduce or minimize scratching of the substrate surfaces during mechanical polishing and when applying a bias to the substrate surface.

Polishing Article Manufacturing

The polishing articles described herein may be manufactured by combining the conductive material and material to form the binder material to form a liquid solution that is then partially cured to form a semi-cured composite material. Abrasive particles of the size described herein are then added to the semi-cured composite material and the semi-cured composite material is then cured to form the polishing article.

The binder material may be formed from multiple chemical components that are mixed together and have polymeric cross-linking reactions to form the binder material. The cross linking reactions solidify the chemical components to provide a solid polishing article. Chemical bonds formed during cross-linking surround the conductive material disposed therein to fix the conductive materials when solidifing. The conductive material is provided in sufficient amount to provide conductive paths through the polymeric cross-linking of the polymer binder material.

For example, polyurethane may be formed by the reaction product of a polyfunctional amine, diamine, triamine or polyfunctional hydroxyl compound or mixed functionality compounds such as hydroxyl/amines, such as an alkene polyol, and an organic polyisocyanate selected from the group of aliphatic, cycloaliphatic or aromatic diisocyanates to permit the formation of urea crosslinked polymer network. Another example of a polyurethane is a polyesterurethane that is a reaction product of a hydroxy functional polyester and an organic polyisocyanate selected from the group of aliphatic, cycloaliphatic or aromatic diisocyanates. An exemplary polyetherurethane is the reaction product of a mixture of polyols, e.g. ethylene glycol, propylene glycol and butanediol and 4,4-diphenylmethane diisocyanate. An exemplary polyesterurethane is the reaction product of dihydroxy polybutylene adipate and methylene bis(4-phenyl isocyanate).

Additives may be added to the binder material to assist the dispersion of conductive material and/or abrasive materials in the polymer materials. Additives may be used to improve the mechanical, thermal, and electrical properties of the polishing material formed from the fibers and/or fillers and the binder material. Additives include cross-linkers for improving polymer cross-linking and dispersants for dispersing conductive fibers or conductive fillers more uniformly in the binder material. Examples of cross-linkers include amino compounds, silane crosslinkers, polyisocyanate compounds, and combinations thereof. Examples of dispersants include N-substituted long-chain alkenyl succinimides, amine salts of high-molecular-weight organic acids, co-polymers of methacrylic or acrylic acid derivatives containing polar groups such as amines, amides, imines, imides, hydroxyl, and ether, ethylene-propylene copolymers containing polar groups such as amines, amides, imines, imides, hydroxyl, and ether. In addition sulfur containing compounds, such as thioglycolic acid and related esters have been observed as effective dispersers for gold coated fibers and fillers in binder materials. The invention contemplates that the amount and types of additives will vary for the materials disposed in the binder material as well as the binder material used, and the above examples are illustrative and should not be construed or interpreted as limiting the scope of the invention.

The liquid mixture of the polyurethane and conductive material, for example, tin, is transferred to a conventional mold before the viscosity of the reacted urethane polymer becomes too great to permit sufficient blending of the conductive material with the polymer mixture. The resulting mixture is gelled in the mold for about 15 minutes. The gelling time may vary based upon factors such as temperature and selection of the material components. The composite is then thermally cured at about 90° C. to about 110° C. for between about 4 and about 6 hours and cooled to room temperature (about 20° C.). The curing times and temperatures and times may vary depending upon the polymer matrix among other factors. The preceding example is illustrative and should not be constructed or interpreted as limiting the scope of the invention.

The abrasive particles as described herein may be added during the curing process. For example, the abrasive particles may be added at one-fourth or one-half of the time of the curing process. Alternatively, the abrasive particles may be added periodically during the curing process. Different amounts and constituents of the abrasive particles may also be added during different times of the curing process to tailor the polishing article with the desired abrasive properties. The timing and the amount of the abrasive particles to be added to a partially or semi-cured composite material will vary by the desired abrasive properties. Alternatively, the abrasive particles may be added following the gelling time and before the curing process. The resulting article is removed from the mold and cut, sliced, or otherwise processed to the desired thickness and shaped to form polishing pads.

Alternatively, the polishing article described herein may be manufactured by combining the conductive material and components of the binder material to form a liquid solution that is then partially cured to form a cured composite polishing article material. The polishing material is then embossed or surface treated, such as by a conditioner, to form recesses or aspects. The abrasive particles are then embedded in the recesses or aspects of the surface of the polishing article. The polishing pad may then be further treated, such as additional thermal processes to ensure abrasive adherence to the surface of the polishing material.

Polishing Article Structures

In one aspect, the polishing article is composed of a single layer of conductive polishing material described herein disposed on a support. In another aspect, the polishing article may comprise a plurality of material layers including at least one conductive material on the substrate surface providing a conductive surface for contacting a substrate and at least one article support portion or sub-pad.

FIG. 3 is a partial cross-sectional view of one embodiment of a polishing article 405. Polishing article 405 illustrated in FIG. 3 comprises a conductive polishing portion 310 as described herein for polishing a substrate surface and an article support, or sub-pad, portion 320.

The conductive polishing portion 310 may comprise a conductive polishing material including the conductive materials as described herein. For example, the conductive polishing portion 310 may include conductive material comprising soft conductive material particles dispersed in a polymeric material. Soft conductive materials generally have a hardness and modulus less than or equal to about that of copper. Examples of soft conductive materials include gold, tin, palladium, palladium-tin alloys, platinum, and lead, among other conductive metals, alloys and ceramic composites softer than copper. The invention contemplates the use of other conductive materials harder than copper if their size is small enough not to scratch polishing substrate. The conductive polishing portion 310 may also be comprised of multiple conductive material components, such as two or more conductive materials, or even non-metallic conductive materials, such as conductive carbon materials, for example, graphite or carbon black. One example of the conductive polishing portion 310 includes gold or tin particles dispersed in polyurethane matrix.

In another embodiment, the conductive polishing portion 310 may have abrasive particles 360 disposed therein. At least some of the abrasive particles 360 are exposed on an upper polishing surface 370 of the conductive polishing portion 310. The abrasive particles 360 generally are configured to remove the passivation layer of the metal surface of the substrate being polished, thereby exposing the underlying metal to the electrolyte and electrochemical activity, thereby enhancing the rate of polishing during processing. Examples of abrasive particles 360 include the abrasive particles described herein.

The article support portion 320 generally has the same or smaller diameter or width as the conductive polishing portion 310. However, the invention contemplates the article support portion 320 having a greater width or diameter than the conductive polishing portion 310. While the figures herein illustrate a circular conductive polishing portion 310 and article support portion 320, the invention contemplates that the conductive polishing portion 310, the article support portion 320, or both may have different shapes such as rectangular surfaces or elliptical surfaces. The invention further contemplates that the conductive polishing portion 310, the article support portion 320, or both, may form a linear web or belt of material.

The article support portion 320 may comprise inert materials in the polishing process and are resistant to being consumed or damaged during ECMP. For example, the article support portion may be comprised of a conventional polishing materials, including polymeric materials, for example, polyurethane and polyurethane mixed with fillers, polycarbonate, polyphenylene sulfide (PPS), ethylene-propylene-diene-methylene (EPDM), polytetrafluoroethylene polymers, or combinations thereof, and other polishing materials used in polishing substrate surfaces. The article support portion 320 may be a conventional soft material, such as compressed felt fibers impregnated with urethane, for absorbing some of the pressure applied between the polishing article 405 and the carrier head 130 during processing. The soft material may have a Shore A hardness between about 20 Shore A and about 90 Shore A.

Alternatively, the article support portion 320 may be made from a conductive material compatible with surrounding electrolyte that would not detrimentally affect polishing, including conductive noble metals or a conductive polymer, to provide electrical conduction across the polishing article. Examples of noble metals include gold, platinum, palladium, iridium, rhenium, rhodium, rhenium, ruthenium, osmium, and combinations thereof, of which gold and platinum are preferred. Materials that are reactive with the surrounding electrolyte, such as copper, may be used if such materials are isolated from the surrounding electrolyte by an inert material, such as a conventional polishing material or a noble metal.

When the article support portion 320 is conductive, the article support portion 320 may have a greater conductivity, i.e., lower resistivity, than the conductive polishing portion 310. For example, the conductive polishing portion 310 may have a resistivity of about 1.0 Ω-cm or less as compared to an article support portion 320 comprising platinum, which has a resistivity 9.81 μΩ-cm at 0° C. A conductive article support portion 320 may provide for uniform bias or current to minimize conductive resistance along the surface of the article, for example, the radius of the article, during polishing for uniform anodic dissolution across the substrate surface. A conductive article support portion 320 may be coupled to a power source for transferring power to the conductive polishing portion 310.

Generally, the conductive polishing portion 310 is adhered to the article support portion 320 by a conventional adhesive suitable for use with polishing materials and in polishing processes. The invention contemplates the use of other means to attach the conductive polishing portion 310 onto the article support portion 320 such as compression molding and lamination. The adhesive may be conductive or dielectric depending on the requirements of the process or the desires of the manufacturer. The article support portion 320 may be affixed to a support, such as disc 206, by an adhesive or mechanical clamp. Alternatively, if polishing article 405 only includes a conductive polishing portion 310, the conductive polishing portion may be affixed to a support, such as disc 206, by an adhesive or mechanical clamp

The conductive polishing portion 310 and the article support portion 320 of the polishing article 405 are generally permeable to the electrolyte. A plurality of perforations 350 may be formed, respectively, in the conductive polishing portion 310 and the article support portion 320 to facilitate fluid flow therethrough. The plurality of perforations allows electrolyte to flow through and contact the surface during processing. The perforations may be inherently formed during manufacturing, such as between weaves in a conductive fabric or cloth, or may be formed and patterned through the materials by mechanical means. The perforations may be formed partially or completely through each layer of the polishing article 405. The perforations of the conductive polishing portion 310 and the perforations of the article support portion 320 may be aligned to facilitate fluid flow therethrough.

Examples of perforations 350 formed in the polishing article 405 may include apertures in the polishing article having a diameter between about 0.02 inches (0.5 millimeters) and about 0.4 inches (10 mm). The thickness of the polishing article 405 may be between about 0.1 mm and about 5 mm. For example, perforations may be spaced between about 0.1 inches and about 1 inch from one another.

The polishing article 405 may have a perforation density between about 20% and about 80% of the polishing article in order to provide sufficient mass flow of electrolyte across the polishing article surface. However, the invention contemplates perforation densities below or above the perforation density described herein that may be used to control fluid flow therethrough. In one example, a perforation density of about 50% has been observed to provide sufficient electrolyte flow to facilitate uniform anodic dissolution from the substrate surface. Perforation density is broadly described herein as the volume of polishing article that the perforations comprise. The perforation density includes the aggregate number and diameter or size of the perforations, of the surface or body of the polishing article when perforations are formed in the polishing article 405.

The perforation size and density is selected to provide uniform distribution of electrolyte through the polishing article 405 to a substrate surface. Generally, the perforation size, perforation density, and organization of the perforations of both the conductive polishing portion 310 and the article support portion 320 are configured and aligned to each other to provide for sufficient mass flow of electrolyte through the conductive polishing portion 310 and the article support portion 320 to the substrate surface.

Grooves may be disposed in the polishing article 405 to promote electrolyte flow across the polishing article 405 to provide effective or uniform electrolyte flow with the substrate surface for anodic dissolution or electroplating processes. The grooves may be partially formed in a single layer or through multiple layers. The invention contemplates grooves being formed in the upper layer or polishing surface that contacts the substrate surface. To provide increased or controlled electrolyte flow to the surface of the polishing article, a portion or plurality of the perforations may interconnect with the grooves. Alternatively, all or none of the perforations may interconnect with the grooves disposed in the polishing article 405.

Examples of grooves used to facilitate electrolyte flow include linear grooves, arcuate grooves, annular concentric grooves, radial grooves, and helical grooves among others. The grooves formed in the article 405 may have a cross-section that is square, circular, semi-circular, or any other shape that may facilitate fluid flow across the surface of the polishing article. The grooves may intersect each other. The grooves may be configured into patterns, such as an intersecting X-Y pattern disposed on the polishing surface or an intersecting triangular pattern formed on the polishing surface, or combinations thereof, to improve electrolyte flow over the surface of the substrate.

The grooves may be spaced between about 30 mils and about 300 mils apart from one another. Generally, grooves formed in the polishing article have a width between about 5 mils and about 30 mils, but may vary in size as required for polishing. An example of a groove pattern includes grooves of about 10 mils wide spaced about 60 mils apart from one another. Any suitable groove configuration, size, diameter, cross-sectional shape, or spacing may be used to provide the desired flow of electrolyte. An example of a pad perforation and grooving as well as additional cross sections and groove configurations are more fully described in co-pending U.S. Patent Provisional Application Ser. No. 60/328,434, filed on Oct. 11, 2001, entitled “Method And Apparatus For Polishing Substrates”, which is incorporated herein by reference in its entirety to the extent not inconsistent with the disclosure and claimed aspects herein. Additional examples of groove patterns, such as spiraling grooves, serpentine grooves, and turbine grooves, are more fully described in co-pending U.S. patent Publication No. 2003/0114084, filed on Oct. 11, 2001, entitled “Method And Apparatus For Polishing Substrates”, which is incorporated herein by reference in its entirety to the extent it is not inconsistent with the disclosure and claimed aspects herein.

Electrolyte transport to the surface of the substrate may be enhanced by intersecting some of the perforations with the grooves to allow electrolyte to enter through one set of perforation, be evenly distributed around the substrate surface by the grooves, used in processing a substrate, and then processing electrolyte is refreshed by additional electrolyte flowing through the perforations.

In addition to the perforations and grooves in the polishing article 405, the conductive polishing portion 310 may be embossed to include surface texture. The embossment may improve the transportation of electrolytes, removed substrate materials, by products, and particles. The embossment may also reduce scratches to polishing substrate and modify the friction between polishing substrate and the polishing article 405. The embossed surface textures distribute uniformly across the conductive polishing portion 310. Embossed surface textures may include structures such as pyramids, islands, crosses along with circular, rectangular and square shapes, among other geometric forms. The invention contemplates other texture structures embossed on conductive polishing portion 310. The embossed surface may cover 5 to 95 percent surface area of the conductive polishing portion 310, such as between 15 percent and 90 percent surface area of the conductive polishing portion 310.

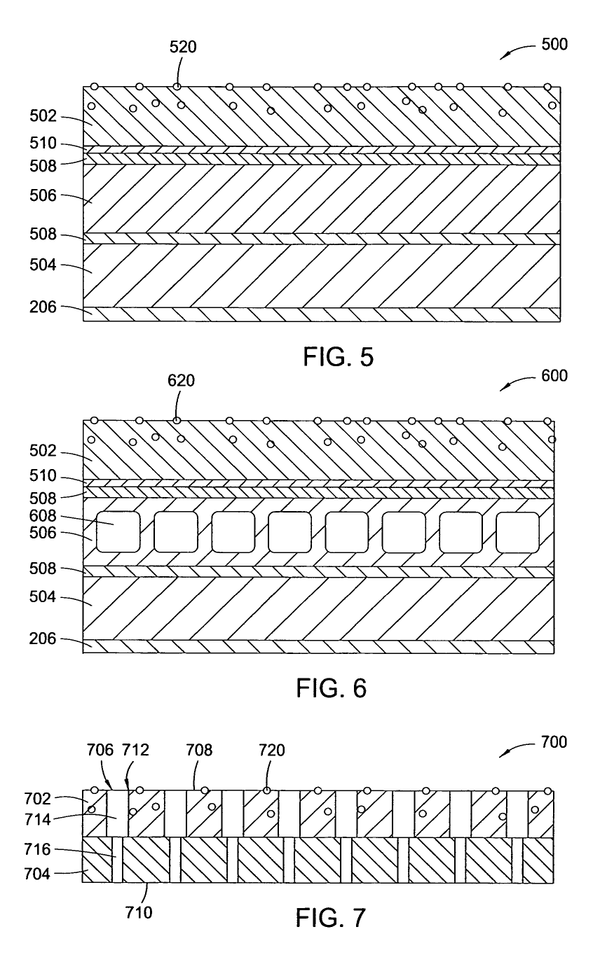

FIG. 5 is a sectional view of another embodiment of a conductive article 500. The conductive article 500 generally includes a conductive portion 502 adapted to contact a substrate during polishing, an article support portion 504 and an interposed pad 506 sandwiched between the conductive portion 502 and the article support portion 504. The conductive portion 502 and article support portion 504 may be configured similar to any of the embodiments described herein or their equivalent. Abrasive particles 520 as described herein are disposed in conductive portion 502. A layer of adhesive 508 may be provided on each side of the interposed pad 506 to couple the interposed pad 506 to the article support portion 504 and the conductive portion 502. The conductive portion 502, the article support portion 504 and the interposed pad 506 may be coupled by alternative methods thereby allowing the components of the conductive article 500 to be easily replaced as a single unit after its service life, simplifying replacement, inventory and order management of the conductive article 500.

Optionally, the support portion 504 may be coupled to an electrode 206 and replaceable with the conductive article 500 as a single unit. The conductive article 500, optionally including the electrode 206, may also include a window formed therethrough as depicted and described with reference to FIG. 4.

The interposed pad 506 is generally harder than the article support portion 504 and is as hard or harder than the conductive portion 502. The invention contemplates the interposed pad 506 may alternatively be softer than the conductive portion 502. The hardness of the interposed pad 506 is selected to provide stiffness to the conductive article 500, which extends the mechanical life of both the conductive portion 502 and the article support portion 504 while improving dampening characteristics of the conductive article 500 resulting in greater global flatness of the polished substrate. In one embodiment, the interposed pad 506 has a hardness of less than or equal to about 80 Shore D, the article support portion 504 has a hardness of less than or equal to about 80 Shore A, while the conductive portion 502 has a hardness of less than or to about 100 Shore D. In another embodiment, the interposed pad 506 has a thickness of less than or equal to about 35 mils, while the article support portion 504 has a thickness of less than or equal to about 100 mils.

The interposed pad 506 may be fabricated from a dielectric material that permits electrical pathways to be established through the laminate comprising the conductive article 500 which may comprise the stack of the conductive portion 502, the interposed pad 506 and the article support portion 504. The electrical pathways may be established as the conductive article 500 is immersed or covered with a conductive fluid, such as an electrolyte. To facilitate the establishment of electrical pathways through the conductive article 500, the interposed pad 506 may be at least one of permeable or perforated to allow electrolyte to flow therethrough.

In one embodiment, the interposed pad 506 is fabricated from a dielectric material compatible with the electrolyte and the electrochemical process. Suitable materials include polymers, such as polyurethane, polyester, mylar sheet, epoxy and polycarbonate, among others.

Optionally, a conductive backing 510 may be disposed between the interposed pad 506 and the conductive portion 502. The conductive backing 510 generally equalizes the potential across the conductive portion 502, thereby enhancing polishing uniformity. Having equal potential across the polishing surface of the conductive portion 502 ensures good electrical contact between the conductive portion 502 and conductive material being polished, particularly if the conductive material is residual material that is no longer a continuous film (i.e., discrete islands of film residue). Moreover, the conductive backing 510 provides mechanical strength to the conductive portion 502, thereby increasing the service life of the conductive article 500. Utilization of the conductive backing 510 is beneficial in embodiments where the resistance through the conductive portion is greater than about 500 m-ohms and enhances the mechanical integrity of conductive portion 502. The conductive backing 510 may also be utilized to enhance the conductive uniformity and lower the electrical resistance of the conductive portion 502. The conductive backing 510 may be fabricated from metal foils, metal screens, metal coated woven or non-woven fabrics among other suitable conductive materials compatible with the polishing process. In one embodiment, the conductive backing 510 is compression molded to the conductive portion 502. The backing 510 is configured not to prevent the flow of electrolyte between the conductive portions 504 and the interposed pad 506. The conductive portion 502 may be mounted onto the conductive backing 510 through compression molding, lamination, injection molding and other suitable methods.

FIG. 6 is sectional view of another embodiment of a conductive article 600. The conductive article 600 generally includes a conductive portion 502 adapted to contact a substrate during polishing, a conductive backing 510, an article support portion 504 and an interposed pad 506 sandwiched between the conductive portion 502 and the article support portion 504, having similar construction to the conductive article 500 described above. Abrasive particles 620 as described herein are disposed in conductive portion 502.

In the embodiment depicted in FIG. 6, the interposed pad 606 is fabricated from a material having a plurality of cells 608. The cells 608 are generally filled with air or other fluid, and provide a resiliency and compliance that enhances processing. The cells may be open or closed with a size ranging from 0.1 μm to several millimeters such as between 1 micron meter to 1 millimeter. The invention contemplates other sizes applicable for interposed pad 606. The interposed pad 606 may be at least one of permeable or perforated to allow electrolyte to flow therethrough.

The interposed pad 606 may be fabricated from a dielectric material compatible with the electrolyte and the electrochemical process. Suitable materials include, but are not limited to, foamed polymers such as foamed polyurethane and mylar sheet. The interposed pad 606 generally has a less compressibility than article support portion or sub-pad 504 and more local deformation independence when subjected to pressure. While not shown in FIGS. 5 and 6, one or more of the material layers as described in FIGS. 5 and 6, for example layers 502, 510, 508, 506, 504, and 206 may be perforated and one or more of the layers, such as layer 502, may be grooved as described herein.

FIG. 7 is sectional view of another embodiment of a conductive article 700. The conductive article 700 includes a conductive portion 702 coupled to an article support portion 704. Optionally, the conductive article 700 may include an interposed pad and conductive backing (both not shown) disposed between the conductive portion 702 and the article support portion 704.

The conductive article 700 generally includes a plurality of apertures 706 formed therethrough to allow electrolyte or other processing fluids to pass between an upper polishing surface 708 of the conductive portion 702 and a lower mounting surface 710 of the article support portion 704. The edge 712 defined where each of the apertures 706 intersects the upper polishing surface 708 is contoured to eliminate any sharp corner, burrs or surface irregularities that may scratch the substrate during processing. The contour of the edge 712 may include a radius, chamfer, taper or other configuration that smoothes the edge 712 and promotes scratch minimization. Abrasive particles 720 as described herein are disposed in conductive portion 702.

In embodiments where the conductive portion 702 is at least partially fabricated from a polymer, the smoothing of the edge 712 may be realized by forming the aperture 706 before the polymer has completely cured. Thus, the edges 712 will become rounded as the conductive portion 702 shrinks during the remainder of polymer curing cycle.

Additionally, or in the alternative, the edges 712 may be rounded by applying at least one of heat or pressure during or after curing. In one example, the edges 712 may be burnished, heat or flame treated to round the transition between the polishing surface 708 and the aperture 706 at the edge 712.

In another example, a polymer conductive portion 702 may be comprised of a moldable material that is repulsive to the mold or die. The repulsive nature of polymer conductive portion 702 causes a surface tension that causes stresses to be molded into the polymer conductive portion 702 that pull the material away from the mold, thereby resulting in the rounding of the edges 712 of the apertures 706 upon curing.

The apertures 706 may be formed through the conductive article 700 before or after assembly. In one embodiment, the aperture 706 includes a first hole 714 formed in the conductive portion 702 and a second hole 716 formed in the article support portion 704. In embodiments comprising an interposed pad, the second hole 716 is formed therein. Alternatively, the first hole 714 and at least a portion of the second hole 716 may be formed in the conductive portion 702. The first hole 714 has a diameter greater than a diameter of the second hole 716. The smaller diameter of the second hole 716 underlying the first hole 714 provides lateral support to the conductive portion 702 surrounding the first hole 714, thereby improving resistance to pad shear and torque during polishing. Thus, the aperture 706 comprising a larger hole at the surface 708 disposed concentric to an underlying smaller hole results in less deformation of the conductive portion 702 while minimizing particle generation, thus minimizing substrate defects incurred by pad damages.

The apertures in the conductive article may be punched through mechanical methods such as male/female punching before or after all layers are put together. In one embodiment the conductive portion 702 compression molded onto conductive backing is first mounted onto an interposed layer, conductive portion 702 with conductive backing and interposed layer are mechanically perforated together, the article support portion or sub-pad is mechanically perforated separately, and after perforation they are aligned together. In another embodiment all layers are put together, and then perforated. The invention contemplates any perforation techniques and sequence.

While foregoing is directed to various embodiments of the invention, other and further embodiments of the invention may be devised without departing from the basic scope thereof, and the scope thereof is determined by the claims that follow.

What is claimed is:

1. A process for manufacturing a polishing article, comprising:
combining a conductive material component and components of a binder material to form a composite material;
at least partially curing the composite material; and
introducing abrasive particles of about 0.01 inch or greater in diameter to form an abrasive-containing composite material.

2. The process of claim 1, further comprising curing the abrasive-containing composite material to form a solid composite material.

3. The process of claim 1, wherein the abrasive particles comprise an inorganic material selected from the group of alumina, ceria, diamond, silica, titania, zirconia, germania, boron nitride, boron carbide, silicon carbide, and combinations thereof, a cured polymeric material selected from the group of polyurethane, polymethylmethacrylate, polymethyl acrylate, polystyrene, polymethacrylonitrile, and combinations thereof, or both.

4. The process of claim 1, wherein the conductive material is selected from the group consisting of gold, tin, palladium, palladium-tin alloys, platinum, lead, and metal alloys and ceramic composites softer than copper.

5. The process of claim 1, wherein the binder material comprises a polymeric material selected from the group of acrylic polymers, fluoropolymers polyurethane, polyester, polyethylene, polypropylene, polycarbonate, polysilicone, polystyrene, diene containing polymers, polyacrylontrile ethylene styrene, polyamides, nylon polymer, polysulfone, ethylene copolymer, polyether, polyether-polyester copolymer, polymethyl methacrylate, polyvinyl chloride, polyethylene copolymer, polyethyleneimine, polyethersulfone, polyetherimide, polyketone, and combinations thereof.

6. The process of claim 1, wherein the conductive material comprises tin, the binder material comprises polyurethane, and the abrasive particles comprise cured polyurethane particles.

7. A polishing article for polishing a substrate, comprising:
a conductive polishing layer comprising a soft conductive material, a binder material, and abrasive particles of about 0.01 inch or greater in diameter; and
an article support layer coupled to and disposed below the conductive polishing layer.

8. The polishing article of claim 7, wherein the soft conductive material is selected from the group consisting of gold, tin, palladium, palladium-tin alloys, platinum, lead, and metal alloys and ceramic composites softer than copper.

9. The polishing article of claim 7, wherein the abrasive particles comprise an inorganic material selected from the group of alumina, ceria, diamond, silica, titania, zirconia, germania, boron nitride, boron carbide, silicon carbide, and combinations thereof, a polymeric material selected from the group of polyurethane, polymethylmethacrylate, polymethyl acrylate, polystyrene, polymethacrylonitrile, and combinations thereof, or both

10. The polishing article of claim 7, wherein the conductive material is selected from the group consisting of gold, tin, palladium, palladium-tin alloys, platinum, lead, and metal alloys and ceramic composites softer than copper.

11. The polishing article of claim 7, wherein the binder material comprises a polymeric material selected from the group of acrylic polymers, fluoropolymers polyurethane, polyester, polyethylene, polypropylene, polycarbonate, polysilicone, polystyrene, diene containing polymers, polyacrylontrile ethylene styrene, polyamides, nylon polymer, polysulfone, ethylene copolymer, polyether, polyether-polyester copolymer, polymethyl methacrylate, polyvinyl chloride, polyethylene copolymer, polyethyleneimine, polyethersulfone, polyetherimide, polyketone, and combinations thereof.

12. The polishing article of claim 7, wherein the conductive material comprises tin, the binder material comprises polyurethane, and the abrasive particles comprise cured polyurethane particles.

13. The polishing article of claim 7, wherein a polishing surface of the conductive polishing layer has a flatness less than or equal to about plus or minus 1 millimeter and a surface roughness less than about 500 microns.

14. The polishing article of claim 7, wherein the conductive polishing layer further comprises an embossed polishing surface.

15. The polishing article of claim 7, wherein the conductive layer and the article support layer further comprises a plurality of perforations formed therethrough.

16. The polishing article of claim 7, further comprising a window disposed through the conductive layer and the article support layer.

17. The polishing article of claim 16, wherein the window further comprises a transparent material disposed in at least one of the conductive layer or the article support layer.

18. The polishing article of claim 7, wherein the conductive polishing layer further comprises a terminal for coupling to a power source.

19. The polishing article of claim 7, further comprising an electrode coupled to and disposed below the article support layer

20. The polishing article of claim 7, further comprising a conductive foil disposed between the conductive polishing layer and the article support layer.
